(19) United States
(12) Patent Application Publication
(10) Pub. No.: US 2026/0197929 A1
(43) Pub. Date: Jul. 9, 2026

(54) DEVICE EMBEDDED PRINTED CIRCUIT BOARDS WITH DIAMOND SUBSTRATES AND METHODS OF MANUFACTURING THE SAME

(71) Applicant: Toyota Motor Engineering & Manufacturing North America, Inc., Plano, TX (US)

(72) Inventors: Tianzhu Fan, Houston, TX (US); Feng Zhou, Ann Arbor, MI (US); Ercan Mehmet Dede, Ann Arbor, MI (US); Shailesh N. Joshi, Ann Arbor, MI (US); Yohei Iwahashi, South Lyon, MI (US)

(73) Assignee: Toyota Motor Engineering & Manufacturing North America, Inc., Plano, TX (US)

(21) Appl. No.: 19/014,697

(22) Filed: Jan. 9, 2025

(51) Int. Cl. H05K 1/02; H05K 1/03; H05K 1/18

(52) U.S. Cl. CPC H05K 1/0201; H05K 1/0306; H05K 1/183; H05K 2201/064

(57) ABSTRACT

A printed circuit board includes a cold plate, a diamond-based core layer bonded to the cold plate, and a at least one circuit board layer with a predefined conductive pattern bonded to the diamond-based core layer. The diamond-based core layer includes a diamond substrate with a cave, a bare die disposed in and bonded to the cave, and conductive through vias extend through the at least one circuit board layer and are in direct contact with the bare die.

### TECHNICAL FIELD

The present disclosure relates to printed circuit boards, and particularly to printed circuit boards with integrated circuits embedded therein.

### BACKGROUND

Printed circuit boards (PCBs) are typically used for mechanical support and electrical connection of electronic components using conductive pathways of copper sheets laminated onto a non-conductive substrate. And multi-layer PCBs provide higher capacity and/or density of electronic components in a smaller footprint by incorporating two or more layers. However, heat dissipation for multilayer PCBs can be difficult.

The present disclosure addresses issues related to the manufacture of multi-layer PCBs and other issues related to multi-layer PCBs.

### SUMMARY

This section provides a general summary of the disclosure and is not a comprehensive disclosure of its full scope or all of its features.

In one form of the present disclosure, a printed circuit board includes a cold plate, a diamond-based core layer bonded to the cold plate, and at least one circuit board layer with a predefined conductive pattern bonded to the diamond-based core layer. The diamond-based core layer includes a diamond substrate with a cave, a bare die disposed in and bonded to the cave, and conductive through vias extend through the at least one circuit board layer and are in direct contact with the bare die.

In another form of the present disclosure, a method of manufacturing a printed circuit includes forming a cave in a diamond substrate, bonding a power device within the cave and forming a diamond-based core layer, bonding the diamond-based core layer to a cold plate, bonding at least one circuit board layer with a predefined conductive pattern to the diamond-based core layer, and forming conductive through vias in the at least one circuit board layer such that at least one of the conductive through vias is in direct contact with the power device.

Further areas of applicability and various methods of enhancing the above technology will become apparent from the description provided herein. The description and specific examples in this summary are intended for purposes of illustration only and are not intended to limit the scope of the present disclosure.

### BRIEF DESCRIPTION OF THE DRAWINGS

The present teachings will become more fully understood from the detailed description and the accompanying drawings, wherein:

FIG. 1 shows a side cross-sectional view of a diamond-based chip-embedded printed circuit board (PCB) according to one form of the present disclosure;

FIG. 1A illustrates a step in manufacturing the diamond-based chip-embedded PCB in FIG. 1;

FIG. 1B illustrates another step in manufacturing the diamond-based chip-embedded PCB in FIG. 1;

FIG. 1C illustrates still another step in manufacturing the diamond-based chip-embedded PCB in FIG. 1;

FIG. 1D illustrates yet another step in manufacturing the diamond-based chip-embedded PCB in FIG. 1;

FIG. 1E illustrates still yet another step in manufacturing the diamond-based chip-embedded PCB in FIG. 1;

FIG. 1F illustrates a step in manufacturing the diamond-based chip-embedded PCB in FIG. 1;

FIG. 1G illustrates another step in manufacturing the diamond-based chip-embedded PCB in FIG. 1;

FIG. 1H illustrates still another step in manufacturing the diamond-based chip-embedded PCB in FIG. 1;

FIG. 1I illustrates yet another step in manufacturing the diamond-based chip-embedded PCB in FIG. 1;

FIG. 1J illustrates still yet another step in manufacturing the diamond-based chip-embedded PCB in FIG. 1;

FIG. 1K illustrates a step in manufacturing the diamond-based chip-embedded PCB in FIG. 1;

FIG. 1L illustrates another step in manufacturing the diamond-based chip-embedded PCB in FIG. 1;

FIG. 1M illustrates still another step in manufacturing the diamond-based chip-embedded PCB in FIG. 1;

FIG. 1N illustrates yet another step in manufacturing the diamond-based chip-embedded PCB in FIG. 1;

FIG. 2 shows a side cross-sectional view of a diamond-based chip-embedded printed circuit board (PCB) according to another form of the present disclosure;

FIG. 2A illustrates a step in manufacturing the diamond-based chip-embedded PCB in FIG. 2;

FIG. 2B illustrates another step in manufacturing the diamond-based chip-embedded PCB in FIG. 2;

FIG. 2C illustrates still another step in manufacturing the diamond-based chip-embedded PCB in FIG. 2; and

FIG. 3 shows a side cross-sectional view of a diamond-based chip-embedded printed circuit board (PCB) according to still another form of the present disclosure;

It should be noted that the figures set forth herein are intended to exemplify the general characteristics of the methods and devices among those of the present technology, for the purpose of the description of certain aspects. The figures may not precisely reflect the characteristics of any given aspect and are not necessarily intended to define or limit specific forms or variations within the scope of this technology.

### DETAILED DESCRIPTION

The present disclosure provides diamond-based chip-embedded printed circuit boards (PCBs) and methods of manufacturing diamond-based chip-embedded PCBs. As used herein, the term “diamond” refers to the solid form of carbon with a diamond cubic crystal structure and the phrase “diamond-based chip-embedded PCB” refers to a multi-layer PCB module or unit with two or more diamond substrates (layers), two or more power semiconductor devices (also referred to herein simply as “power device” or “power devices”) embedded in and bonded to a diamond substrate, control/drive/protection electronic circuitry, and passive components. Also, as used herein, the phrase “power device” refers to a semiconductor device used as a switch or rectifier in power electronics. The diamond can be artificial diamond formed using a high pressure-high temperature (HPHT) process, a chemical vapor deposition (CVD) process, among others.

Diamond-based chip-embedded PCBs according to the teachings of the present disclosure can include a cold plate with a diamond-based core layer bonded to the cold plate. The diamond-based core layer includes two or more power devices embedded within one or more caves in a diamond substrate. For example, in some variations, the two or more power devices are disposed at least partially within two or more caves in a diamond substrate to form a diamond-based core layer, a first surface of the diamond core layer is bonded directly to the cold plate, and one or more circuit board layers, with predefined conductive patterns, are bonded to a second surface, oppositely disposed or positioned from the first surface, of the diamond-based core player.

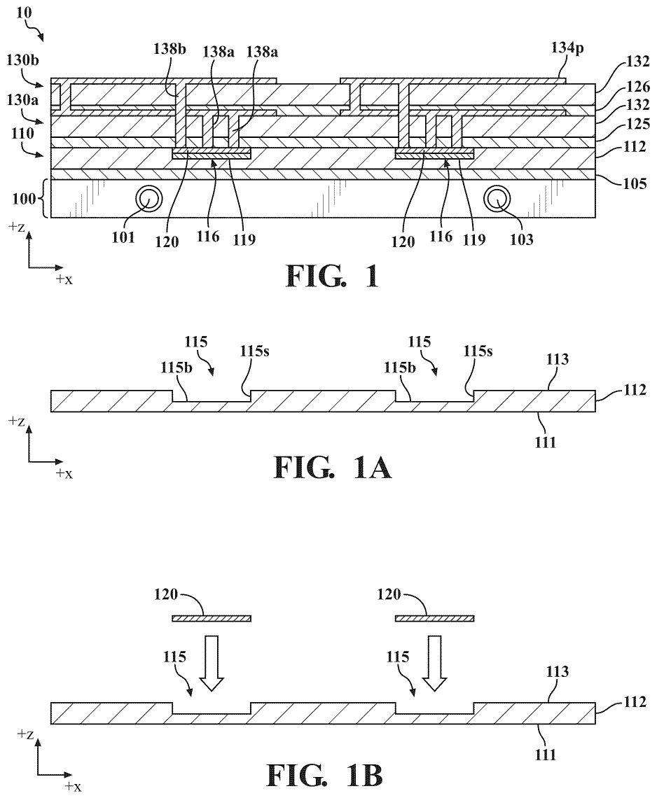

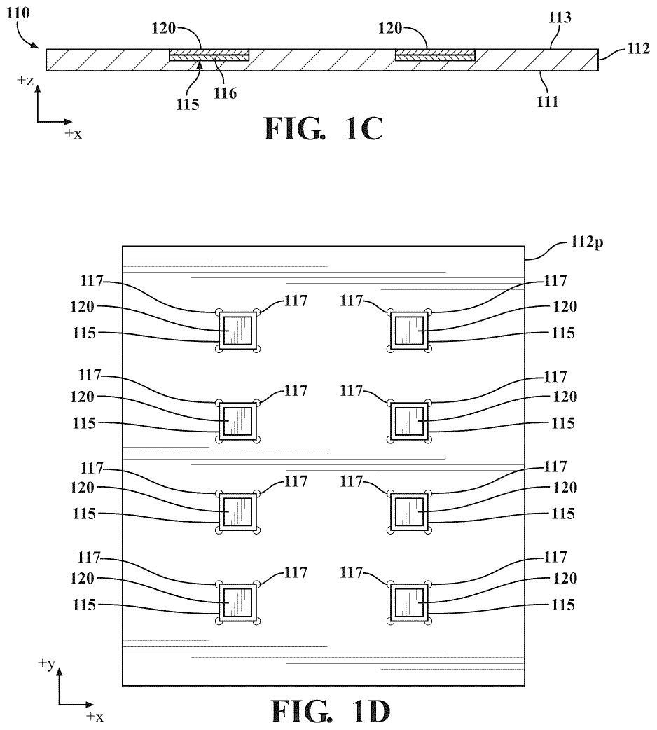

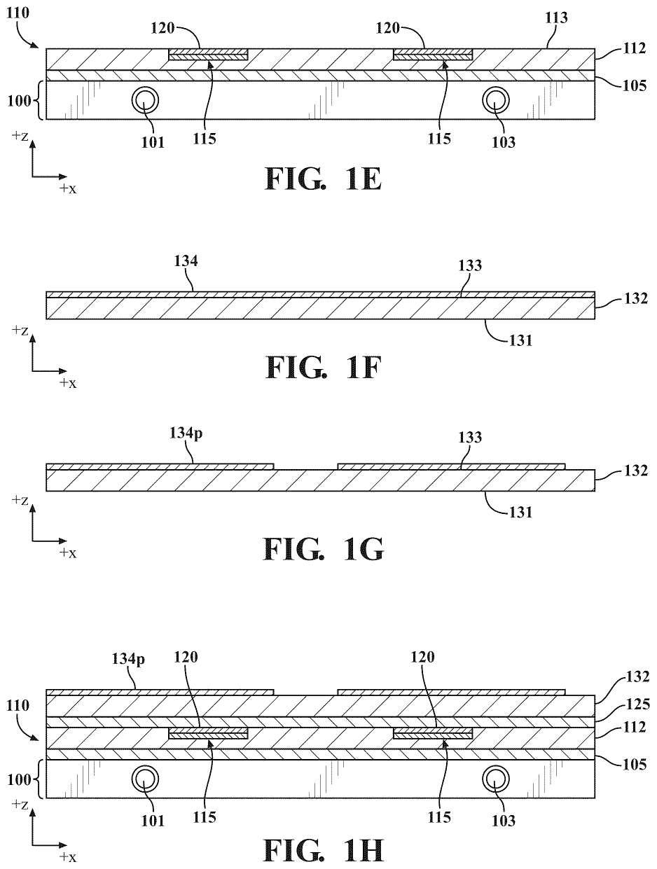

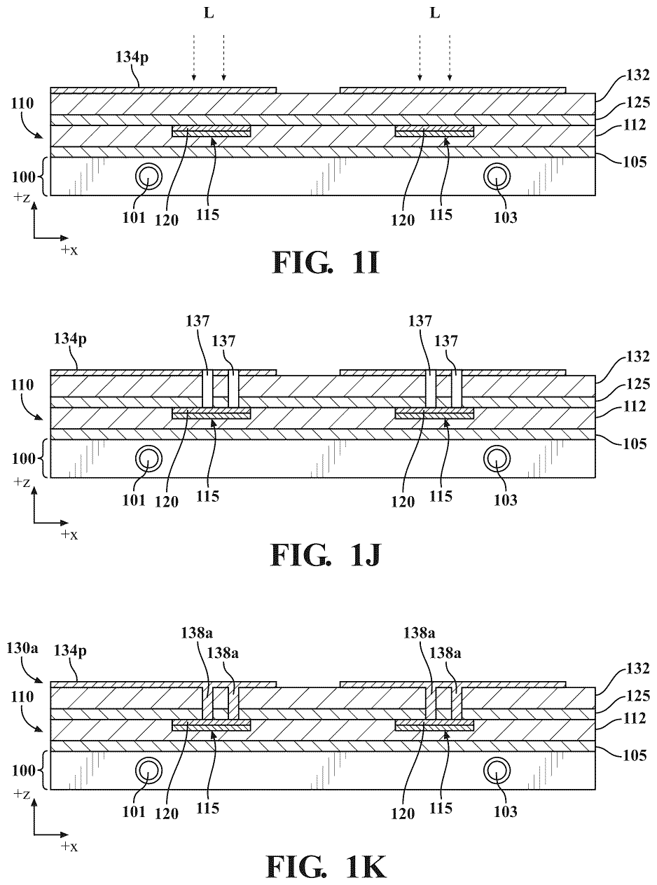

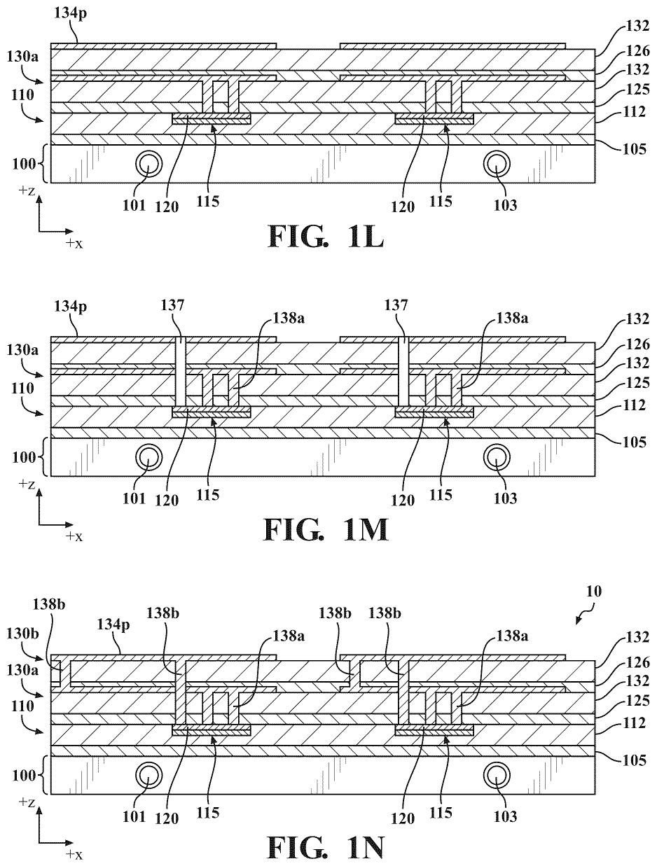

Referring now to FIG. 1, a cross-sectional view of an asymmetric chip-embedded PCB in the form of a diamond-based chip-embedded PCB 10 is shown. As used herein, the phrase “asymmetric chip-embedded PCB” refers to a chip-embedded PCB with a core layer not evenly positioned or disposed between a plurality of circuit board layers. That is, there are a greater number of circuit board layers bonded to one side of the core layer than are bonded to an opposite side of the core layer. As used herein, the phrase “circuit board layer” refers to PCB layer or substrate with control/drive/protection electronic circuitry and/or passive components, but without a power device embedded therein.

The diamond-based chip-embedded PCB 10 includes a cold plate 100, a diamond-based core layer 110 and a plurality of circuit board layers 130a-130b (collectively referred to herein as “diamond-based circuit board layers 130”). In some variations, the cold plate 100 is a fluid (e.g., water) cooled cold plate 100 with a fluid inlet 101 and a fluid outlet 103. In other variations, the cold plate 100 is a two-phase cooling device, a vapor chamber, an air-cooled heat sink, or a glass manifold as discussed in greater detail below (FIG. 3). And it should be understood that the diamond-based chip-embedded PCB 10 can include more than two circuit board layers 130, e.g., three circuit board layers 130, four circuit board layers 130, etc. In addition, the circuit board layers 130 can be independently selected from a diamond-based circuit board layer, an FR4-based circuit board layer, a glass-based circuit board layer, and a ceramic-based circuit board layer as described below.

The diamond-based core layer 110 includes a diamond substrate 112 with two or more bare dies 120 (e.g., a pair of bare dies 120) embedded in and bonded to the diamond substrate 112 via a bonding layer 116. As used herein, the phrase “bare die” refers to a semiconductor (e.g., silicon) chip that contains an integrated circuit and is not packaged in a protective enclosure.

In some variations, the diamond substrate 112 includes two or more caves 115 and the bare dies 120 are bonded directly to the caves 115, i.e., a heat spreader is not present between the bare dies 120 and the diamond substrate 112. As used herein, the phrase “heat spreader” refers a thermally conductive object, formed separately from a bare die and a substrate, that conducts heat away from a bare die. Accordingly, the diamond-based core layer 110 is a non-heat-spreader (or heat spreader free) diamond-based core layer 110. And it should be understood that traditional chip-embedded PCBs typically require a heat spreader bonded to a bare die in order to enhance heat dissipation therefrom. However, the thermal conductivity of the diamond substrate 112 (~2,220 W/(m·K)) provides desired heat dissipation from the bare dies 120 such that heat spreaders are not present, thereby simplifying the design and manufacture of the diamond-based chip-embedded PCB 10.

Each of the circuit board layers 130 includes a substrate 132, control/drive/protection electronic circuitry 134 (also referred to herein simply as “conductive pattern 134”), and one or more conductive through vias 138a, 138b (also referred to herein collectively as “predefined conductive through vias 138”) extending between a lower (−z direction) surface and an upper (+z direction) surface of a given layer 132. In some variations, one or more of the conductive through vias 138a is in directed contact with a bare die 120 and one or more of the conductive through vias 138b is also in direct contact with a bare die. For example, in some variations the bare dies 120 are lateral bare dies 120. As used herein, the “lateral bare die” refers to a bare die with a lateral architecture such that current flows from side (+x direction) to side (−x direction) of the bare die. Accordingly, during operation of the diamond-based chip-embedded PCB 10 electrical signals traverse along the predefined conductive patterns 134p and conductive through vias 138a, 138b to and from an upper (+z direction) surface of the lateral bare dies 120 such that data and instructions provide for the exchange of information between the bare dies and other electrical components.

As noted above, the circuit board layers 130 can be independently selected from a diamond-based circuit board layer, an FR4-based circuit board layer, a glass-based circuit board layer, and a ceramic-based circuit board layer as described below. Accordingly, in some variations, the substrate 132 for the circuit board layer 130a and/or circuit board layer 130b, and other circuit board layers disclosed herein, is a diamond substrate, while in other variations, the substrate 132 for the circuit board layer 130a and/or circuit board layer 130b, and other circuit board layers disclosed herein, is a glass substrate or a ceramic substrate. And in at least one variation, the substrate 132 for the circuit board layer 130a and/or circuit board layer 130b, and other circuit board layers disclosed herein, is an FR4 substrate. As used herein, the term glass refers to an amorphous or non-crystalline solid that is transparent and chemically inert, the phrase “chemically inert” refers to not being chemically reactive or active with materials and/or chemicals used during the manufacture and/or usage of PCBs, and the acronym “FR4” refers to a composite material of woven fiberglass in a flame-retardant epoxy resin.

Referring to FIGS. 1A-1N, steps for the manufacture of the diamond-based chip-embedded PCB 10 according to one or more methods are illustrated. With reference to FIG. 1A, one step of manufacturing the diamond-based chip-embedded PCB 10 includes forming a cave 115 (e.g., two caves 115) in a diamond substrate 112. As used herein, the term “cave” refers to a depression or pocket, within a diamond substrate 112, dimensioned and/or configured for a bare die 120 to be at least partially embedded or seated therein. The diamond substrate 112 has a predefined thickness (z-direction), width (x-direction), and length (y-direction). In some variations, the diamond substrate 112 has a thickness between about 100 micrometers (μm) and about 2.0 millimeter (mm). For example, the diamond substrate can have a thickness between about 100 μm and about 200 μm, between about 200 μm and about 300 μm, between about 300 μm and about 400 μm, between about 400 μm and about 500 μm, between about 500 μm and about 600 μm, between about 600 μm and about 700 μm, between about 700 μm and about 800 μm, between about 800 μm and about 900 μm, between about 900 μm and about 1.0 mm, between about 1.0 mm and about 1.5 mm, or between about 1.5 mm and about 2.0 mm.

The cave 115 extends from a second surface 113 towards a first surface 111 of the diamond substrate 112 and includes a base wall (surface) 115b and at least one side wall 115s. The cave 115 is formed using known or yet to be developed diamond cutting and machining techniques such as laser cutting ablation, waterjet cutting, rotary sawing, and girdle sawing, among others. In addition, the cave 115 has a predefined width (x-direction), length (y-direction), and depth (z-direction) such that a vertical bare die 120 can be disposed or seated within the cave 115.

In some variations, the depth of the cave 115 is generally equal to a thickness (z-direction) of a vertical bare die 120 bonded thereto such that an upper (+z direction) surface of the vertical bare die 120 is generally planar with the second surface 113 of the diamond substrate 112 (FIG. 1C). In other variations, the depth of the cave 115 is greater than a thickness (z-direction) of a vertical bare die 120 bonded thereto such that an upper (+z direction) surface of the vertical bare die 120 is below (−z direction) the second surface 113 of the diamond substrate 112. And in at least one variation, the depth of the cave 115 is less than a thickness (z-direction) of a vertical bare die 120 bonded thereto such that an upper (+z direction) surface of the vertical bare die 120 is above (+z direction) the second surface 113 of the diamond substrate 112.

Referring to FIGS. 1B-1C, bare dies 120 are bonded to the diamond substrate 112 to form a diamond-based core layer 110. For example, bare dies 120 (i.e., semiconductor chips) are desirably positioned within and bonded to the base wall 115b of the caves 115, and thereby bonded to the diamond substrate 112, via bonding layer 116. In some variations, the bonding layer 116 is a dielectric layer such that the bare dies 120 are electrically insulated from the cave 115. Also, the bare dies 120 can be bonded to the diamond substrate caves 115 using bonding techniques such as surface activated bonding, adhesive bonding, among others. For example, and with respect to surface activated bonding, the lower (-z direction) surface of the bare die 120 and the base wall 115b of the cave 115 are polished such that the surface root-mean-square (RMS) roughness of each surface is less than about 1 nanometer (nm). Then, a thin metallic cover layer is applied to the base wall 115b, and under ultra-high vacuum an argon (Ar) fast atomic beam is used to activate the surface of the bare die 120 and the base wall 115b before, and still under ultra-high vacuum, the bare die 120 is placed within the cave and the lower surface of the bare die 120 and the base wall 115b are bonded to each other.

Referring to FIG. 1D, in some variations a plurality of diamond-based core layers 110 are formed on or in a diamond panel 112p per the steps discussed above with respect to FIGS. 1A-1C. That is, a plurality of rows (x-direction) of caves 115 are formed in the diamond panel 112p and a plurality of bare dies 120 are desirably positioned at least partially within the caves 115 and bonded to the diamond panel 112p as illustrated in FIG. 1D. And in such variations, stress relieve structures 117 can be formed at corners of the caves 115 such that the initiation and/or propagation of cracks at the corners of the caves 115 is inhibited. Also, the diamond panel 112p is cut, either before or after the steps discussed below with respect to FIGS. 1E-1N, along the x-direction and/or y-direction shown in the figures to provide a plurality diamond-based core layers 110.

Referring to FIG. 1E, another step for the manufacture of the diamond-based chip-embedded PCB 10 includes bonding the diamond-based core layer 110 to the cold plate 100 via a bonding layer 105. In some variations, the bonding layer 105 is a dielectric layer that is thermally conductive and electrically insulating.

Referring to FIGS. 1F-1N, other steps for the manufacture of the diamond-based chip-embedded PCB 10 are illustrated. For example, and with reference to FIG. 1F, forming an electrically conductive layer 134 (also referred to herein simply as “conductive layer 134”) on a first surface 131 (not shown) and/or on a second surface 133 of a substrate 132 is shown. The substrate 132 has a predefined thickness (z-direction), width (x-direction), and length (y-direction). In some variations, the substrate 132 is a diamond substrate and has a thickness between about 75 micrometers (μm) and about 1.0 millimeter (mm). For example, the diamond substrate can have a thickness between about 75 μm and about 150 μm, between about 150 μm and about 225 μm, between about 225 μm and about 300 μm, between about 300 μm and about 375 μm, between about 375 μm and about 450 μm, between about 450 μm and about 525 μm, between about 525 μm and about 600 μm, between about 600 μm and about 700 μm, or between about 700 μm and about 800 μm, between about 800 μm and about 900 μm, or between about 900 μm and about 1000 μm. In other variations, the substrate 132 is a glass or FR4 substrate and has a thickness between about 0.5 millimeters (mm) and about 5.0 mm.

The conductive layer 134 is formed or applied to the substrate 132 using any method or technique known or yet to be discovered, including chemical vapor deposition (CVD), physical vapor deposition (PVD), sputtering coating, directed bonded copper (DBC), direct plated copper (DPC), stencil/vacuum plating, screen printing, and inkjet printing, among others. Also, the conductive layer 134 is formed from an electrically conducting material (e.g., copper (Cu), silver (Ag), or alloys thereof) and in some variations has a predefined thickness between about 35 micrometers (μm) and about 105 μm.

Referring to FIG. 1G, etching the conductive layer 134 to form a predefined conductive pattern 134p on the first surface 131 and/or on the second surface 133 of the substrate 132 is shown and bonding the substrate 132 with the predefined conductive pattern 134p to the diamond-based core layer 110 via bonding layer 125 is shown in FIG. 1H. In some variations, the bonding layer 125 is a dielectric layer that is thermally conductive and electrically insulating. Also, bonding of the substrate 132 to the diamond-based core layer 110 via bonding layer 125 can be performed using known or yet to be discovered bonding techniques such as adhesive bonding (UV or thermal curable), diamond frit bonding, surface activated bonding (SAB), among others. Accordingly, the bonding layer 125 can be an adhesive layer or a diamond frit layer, among others.

Referring to FIGS. 1I-1K, a laser ‘L’, or some other drilling device, drills or forms vias 137 in and through the substrate 132 (FIGS. 1I-1J), and predefined conductive pattern 134p if present, and bonding layer 125, and conductive through vias 138a are formed such that the predefined conductive pattern 134p is in electrical contact with the diamond-based core layer 110 (FIG. 1K). In some variations, and as illustrated in FIG. 1K, the conductive through vias 138a are in direct contact with the bare dies 120. In this manner, the circuit board layer 130a is formed and bonded to the diamond-based core layer 110. It should be understood that the steps for forming the circuit board layer 130a can be performed or executed in a different order or sequence than as illustrated in FIGS. 1F-1K. For example, one alternative sequence can include forming the vias 137 and/or the conductive through vias 138 in the substrate 132 before the substrate 132 is bonded to the diamond-based core layer 110. In addition, in some variations, the vias 137 are pre-treated with seed material (e.g., Cu) such that pre-treated vias (not shown) are formed, and then conductive material (e.g., Cu) is added to the pre-treated vias to form the conductive through vias 138a.

In some variations, and with reference to FIGS. 1L-1N, additional steps for the manufacture of the diamond-based chip-embedded PCB 10 can include bonding another substrate 132 with a predefined conductive pattern 134p to the circuit board layer 130a such that circuit board layer 130b is formed. And as noted above, the substrate 132 can be a diamond substrate, a glass substrate, an FR4 substrate, or a ceramic substrate, among others. It should be understood that the circuit board layer 130b can be formed as described above with respect to circuit board layer 130a, i.e., a conductive layer 134 is formed or applied to the substrate 132 (FIG. 1F), and the conductive layer 134 is etched to form a predefined conductive pattern 134p (FIG. 1G).

The substrate 132 with the conductive pattern 134p is bonded to the circuit board layer 130a with bonding layer 126 (FIG. 1L) and a laser ‘L’, or some either drilling device, drills or forms vias 137 (FIGS. 1I-1J) in and through the substrate 132 (FIG. 1M), and predefined conductive pattern 134p if present, and the bonding layer 126. The vias 137 may or may not be pre-treated with seed material (e.g., Cu) such that pre-treated vias are formed, and conductive material (e.g., Cu) is added to the vias 137, or pre-treated vias (not shown) to form the conductive through vias 138b (FIG. 1N). In some variations, and as illustrated in FIG. 1N, the conductive through vias 138b are in direct contact with the bare dies 120. And as noted above with respect to forming the circuit board layer 130a, it should be understood that the steps for forming the circuit board layer 130b can be performed or executed in a different order or sequence.

It should be understood that the steps illustrated in FIGS. 1A-1N can be executed or performed in different orders or sequences than as discussed above. For example, bonding of the diamond-based core layer 110 to the cold plate 100 via bonding layer 105 can occur after the step illustrated in FIG. 1H, after the step illustrated in FIG. 1I-1J, after the step illustrated in FIG. 1I-1K, after the step illustrated in FIG. 1L, after the step illustrated in FIG. 1M, or after the step illustrated in FIG. 1N.

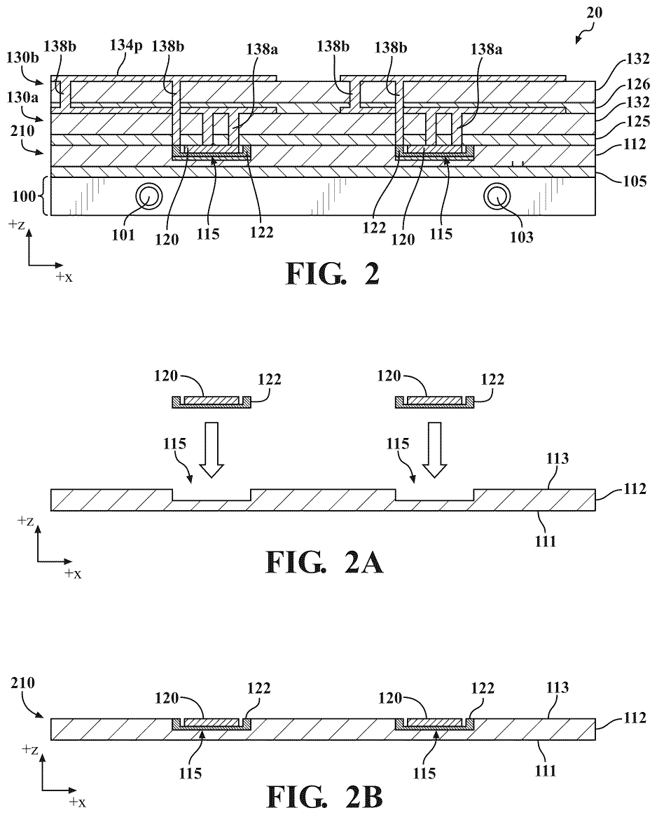

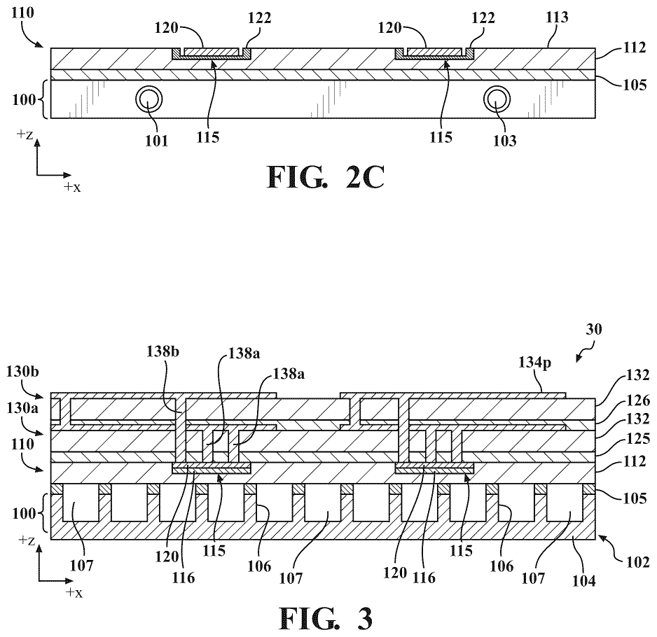

Referring now to FIG. 2, a cross-sectional view of another asymmetric chip-embedded PCB in the form of a diamond-based chip-embedded PCB 20 is shown. The diamond-based chip-embedded PCB 20 includes the cold plate 100 and a plurality of circuit board layers 130a, 130b. However, and unlike the diamond-based chip-embedded PCB 10, the bare dies 120 are bonded to an electrically conductive substrate 122 and the electrically conductive substrate 122 is bonded to the cave 115. Non-limiting examples of a material from which the electrically conductive substrate 122 is formed include copper and copper alloys, other metals and alloys, carbon-based materials, among others.

Referring to FIGS. 2A-2C, steps for the manufacture of the diamond-based chip-embedded PCB 20 are shown. Particularly, a bare die 120 is bonded to an electrically conductive substrate 122 that is bonded to a cave of a diamond substrate to form a diamond-based core layer 210 (FIG. 2B). Also, the diamond-based core layer 210 is bonded to the cold plate 100 with the bonding layer 105 (FIG. 2C), the circuit board layers 130a is bonded to the diamond-based core layer 210 with bonding layer 125 (FIG. 2), and the circuit board layer 130b is bonded to the circuit board layer 130a with the bonding layer 126 (FIG. 2). And as illustrated in FIG. 2, in some variations the bare die 120 is a vertical bare die and a conductive through via 138b is in direct contact with the electrically conductive substrate 122. And as used herein, the phrase “vertical bare die” refers to a bare die with a vertical architecture such that current flows from top (+z direction) to bottom (−z direction) of the bare die. It should be understood that the circuit board layers 130a, 130b and/or the conductive through vias 138a, 138b can be formed as described above with respect to FIGS. 1F-1N.

Referring now to FIG. 3, a cross-sectional view of still another asymmetric chip-embedded PCB in the form of a diamond-based chip-embedded PCB 30 is shown. The diamond-based chip-embedded PCB 30 includes the diamond-based core layer 110 and the plurality of circuit board layers 130a, 130b. However, and unlike the diamond-based chip-embedded PCBs 10, 20, the cold plate 100 is in the form of a manifold 102 with a plurality of flow channels 107 (also referred to herein as “fluid channels”). As used herein, the term “manifold” refers to a cooling structure for a diamond-based chip-embedded PCB that has a plurality of flow channels extending between a plurality of columns and a diamond-based core layer of the diamond-based chip-embedded PCB is bonded directly to the plurality of columns. For example, in some variations the manifold 102 includes a base layer 104 and columns 106 extending from the base layer 104 and towards the diamond-based core layer 110. And in such variations, an upper (+z direction) surface of the columns 106 is bonded to a lower (−z direction) surface of the diamond-based core layer 110 with a bonding layer 105. Accordingly, the diamond-based core layer is bonded to the manifold 102 with the bonding layer 105, the circuit board layer 130a is bonded to the diamond-based core layer 210 with bonding layer 125, and the circuit board layer 130b is bonded to the circuit board layer 130a with the bonding layer 126. Non-limiting examples of material from which the manifold is formed include glass, aluminum, aluminum alloys, other metals and alloys, ceramics, polymers, among others,

As illustrated in FIG. 3, in some variations the bare die 120 is a lateral bare die and a conductive through via 138b is in direct contact with the bare die 120. However, it should be understood that in other variations the bare dies 120 are vertical bare dies, the vertical bare dies 120 are bonded to electrically conductive substrates 122, the electrically conductive substrates 122 are bonded to the caves 115, and the conductive through vias 138b are in direct contact with the electrically conductive substrates 122 as illustrated in FIG. 2. It should also be understood that the circuit board layers 130a, 130b and/or the conductive through vias 138a, 138b can be formed as described above with respect to FIGS. 1F-1N.

The preceding description is merely illustrative in nature and is in no way intended to limit the disclosure, its application, or its uses. Work of the presently named inventors, to the extent it may be described in the background section, as well as aspects of the description that may not otherwise qualify as prior art at the time of filing, are neither expressly nor impliedly admitted as prior art against the present technology.

The figures illustrate the functionality and operation of possible implementations of methods and systems according to various forms or variations. In this regard, each block in the block diagram may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

As used herein, the phrase at least one of A, B, and C should be construed to mean a logical (A or B or C), using a non-exclusive logical “or.” It should be understood that the various steps within a method may be executed in different order without altering the principles of the present disclosure. Disclosure of ranges includes disclosure of all ranges and subdivided ranges within the entire range.

The headings (such as “Background” and “Summary”) and sub-headings used herein are intended only for the general organization of topics within the present disclosure and are not intended to limit the disclosure of the technology or any aspect thereof. The recitation of multiple variations or forms having stated features is not intended to exclude other variations or forms having additional features, or other variations or forms incorporating different combinations of the stated features.

As used herein the term “about” when related to numerical values herein refers to known commercial and/or experimental measurement variations or tolerances for the referenced quantity. In some variations, such known commercial and/or experimental measurement tolerances are +/−10% of the measured value, while in other variations such known commercial and/or experimental measurement tolerances are +/−5% of the measured value, while in still other variations such known commercial and/or experimental measurement tolerances are +/−2.5% of the measured value. And in at least one variation, such known commercial and/or experimental measurement tolerances are +/−1% of the measured value.

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The phrase “at least one of . . . and . . . .” as used herein refers to and encompasses any and all possible combinations of one or more of the associated listed items. As an example, the phrase “at least one of A, B, and C” includes A only, B only, C only, or any combination thereof (e.g., AB, AC, BC, or ABC).

As used herein, the terms “comprise” and “include” and their variants are intended to be non-limiting, such that recitation of items in succession or a list is not to the exclusion of other like items that may also be useful in the devices and methods of this technology. Similarly, the terms “can” and “may” and their variants are intended to be non-limiting, such that recitation that a form or variation can or may comprise certain elements or features does not exclude other forms or variations of the present technology that do not contain those elements or features.

The broad teachings of the present disclosure can be implemented in a variety of forms. Therefore, while this disclosure includes particular examples, the true scope of the disclosure should not be so limited since other modifications will become apparent to the skilled practitioner upon a study of the specification and the following claims. Reference herein to one variation, or various variations means that a particular feature, structure, or characteristic described in connection with a form or variation or particular system is included in at least one variation or form. The appearances of the phrase “in one variation” (or variations thereof) are not necessarily referring to the same variation or form. It should also be understood that the various method steps discussed herein do not have to be conducted in the same order as depicted, and not each method step is required in each variation or form.

The foregoing description of the forms and variations has been provided for purposes of illustration and description. It is not intended to be exhaustive or to limit the disclosure. Individual elements or features of a particular form or variation are generally not limited to that particular form or variation, but, where applicable, are interchangeable and can be used in a selected form or variation, even if not specifically shown or described. The same may also be varied in many ways. Such variations should not be regarded as a departure from the disclosure, and all such modifications are intended to be included within the scope of the disclosure.

What is claimed is:

1. A printed circuit board comprising:
a cold plate;
a diamond-based core layer bonded to the cold plate, the diamond-based core layer comprising a diamond substrate with a cave, and a bare die disposed in and bonded to the cave;
at least one circuit board layer with a predefined conductive pattern bonded to the diamond-based core layer; and
conductive through vias extending through the at least one circuit board layer and in direct contact with the bare die.

2. The printed circuit board according to claim 1, wherein the at least one circuit board layer comprises a first circuit board layer and a second circuit board layer bonded to the first circuit board layer.

3. The printed circuit board according to claim 2 further comprising at least one additional conductive through via extending through the second circuit board layer and in direct contact with the bare die.

4. The printed circuit board according to claim 3, wherein at least one of the first circuit board layer and the second circuit board layer is a diamond-based circuit board layer.

5. The printed circuit board according to claim 3, wherein at least one of the first circuit board layer and the second circuit board layer is an FR4-based circuit board layer.

6. The printed circuit board according to claim 3, wherein at least one of the first circuit board layer and the second circuit board layer is selected from the group consisting of a glass-based circuit board layer and a ceramic-based circuit board layer.

7. The printed circuit board according to claim 1, wherein the at least one circuit board layer comprises three or more circuit board layers bonded to each other, each of the three or more circuit board layers independently selected from the group consisting of a diamond-based circuit board layer, an FR4-based circuit board layer, a glass-based circuit board layer, and a ceramic-based circuit board layer.

8. The printed circuit board according to claim 1, wherein the cold plate is selected from the group consisting of a fluid cooled cold plate with a fluid inlet and a fluid outlet and a manifold with a plurality of flow channels.

9. The printed circuit board according to claim 1, wherein the bare die is a lateral bare die.

10. The printed circuit board according to claim 1 further comprising an electrically conductive substrate disposed in and bonded to the cave, and wherein the bare die is bonded directly to the electrically conductive substrate.

11. The printed circuit board according to claim 10, wherein the electrically conductive substrate is disposed between and in direct contact with the bare die and the cave.

12. The printed circuit board according to claim 11, wherein the bare die is a vertical bare die.

13. The printed circuit board according to claim 12, wherein the circuit board layer is a first circuit board layer and further comprising:
a second circuit board layer bonded to the first circuit board layer; and
at least one additional conductive via extending through the second circuit board layer and in direct contact with the electrically conductive substrate.

14. The printed circuit board according to claim 1, wherein cave is a pair of caves and the bare die is a pair of bare dies disposed in and bonded to the pair of caves such that each of the pair of caves has one of the pair of bare dies bonded thereto.

15. A method comprising:
forming a cave in a diamond substrate;
bonding a power device within the cave and forming a diamond-based core layer;
bonding the diamond-based core layer to a cold plate;
bonding at least one circuit board layer with a predefined conductive pattern to the diamond-based core layer; and
forming conductive through vias in the at least one circuit board layer such that at least one of the conductive through vias is in direct contact with the power device.

16. The method according to claim 15, wherein the at least one circuit board layer is a first circuit board layer with a first predefined conductive pattern and further comprising:
bonding a second circuit board layer with a second predefined conductive pattern to the first circuit board layer; and
forming additional conductive through vias in the second circuit board layer.

17. The method according to claim 16, wherein at least one of the additional conductive through vias is in direct contact with the power device.

18. The method according to claim 16 further comprising bonding the power device to an electrically conductive substrate such that the electrically conductive substrate with the power device bonded thereto is bonded within the cave.

19. The method according to claim 18, wherein at least one of the additional conductive through vias is in direct contact with the electrically conductive substrate.

20. The method according to claim 15, wherein the cold plate is selected from the group consisting of a fluid cooled cold plate with a fluid inlet and a fluid outlet and a manifold with a plurality of flow channels.
